(19) United States
(12) Patent Application Publication
(10) Pub. No.: US 2006/0157698 A1
(43) Pub. Date: Jul. 20, 2006

(54) Semiconductor manufacturing system, semiconductor device and method of manufacture

(75) Inventor: Hiroki Miyajima, Nagaokakyou-shi (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/274,346

(22) Filed: Nov. 16, 2005

(30) Foreign Application Priority Data
Jan. 14, 2005 (JP) 2005-006959

(51) Int. Cl. H01L 21/66; H01L 23/58

(52) U.S. Cl. 257/48; 438/14

(57) ABSTRACT

A semiconductor manufacturing system for accurately recognizing the timing of maintenance of the system includes a processing chamber (101) and a movable member (107) moving in and out of the processing chamber (101). The movable member (107) has a sensor (106) for observing a state in the processing chamber (101).

### FIELD OF THE INVENTION

The present invention relates to a semiconductor manufacturing technique and particularly relates to a semiconductor manufacturing system which makes it possible to recognize a state of a processing chamber of the manufacturing system, improve the working ratio of the semiconductor manufacturing system, and prevent a reduction in yield, and a method of manufacturing a semiconductor device by unit of the manufacturing system.

### BACKGROUND OF THE INVENTION

In processes of manufacturing semiconductor devices, capital investment increases in response to the finer design rules of semiconductor devices in recent years, and thus it is necessary to more efficiently make a profit including the recovery of capital investment. Hence, it is absolutely essential to reduce the cost of manufacturing processes and improve the yields of the manufacturing processes.

In each of the manufacturing processes, in order to prevent process variations caused by the temporal variation of a system and prevent yields from being reduced by particles, a state of the manufacturing system is managed and maintenance is regularly performed for the system.

To be specific, considering that characteristics vary and particles increase with the number of processed wafers, maintenance of a processing chamber is regularly performed at the empirically set number of processed wafers.

Even before reaching the set number of processed wafers, particles are measured and characteristics such as an etching rate, a deposition rate, and film characteristics are managed by a monitor wafer for each lot or every day. When an unexpected abnormality is detected, maintenance of the processing chamber is irregularly performed.

However, in the conventional method of manufacturing a semiconductor device, whether maintenance should be performed or not is decided by an empirical parameter which is the number of processed wafers, and thus the timing of maintenance cannot be accurately recognized. For example, even when maintenance is not actually necessary, maintenance is unnecessarily performed and the working ratio of a facility decreases. Further, when an abnormality unexpectedly occurs and maintenance is necessary, management using a monitor wafer may not detect an abnormality. Thus, lot processing may be performed without detecting an abnormality and result in low yields.

In the event of such an unexpected abnormality, the abnormality can be easily recognized by visually inspecting a device processing chamber. In the case where the device processing chamber is opened to the air and a visual inspection is carried out, maintenance is necessary and the working ratio of a facility decreases.

As unit for recognizing a state in a processing chamber in response to this problem, Japanese Patent Laid-Open No. 2000-3905 and so on disclose the following method:

On a reflecting mirror mounted in a processing chamber, infrared rays are emitted from an infrared spectroscopy monitor outside the processing chamber through a chamber window of the processing chamber, and the thickness of a reaction product deposited on the reflecting mirror is monitored according to a quantity of reflected light, so that a state in the processing chamber is recognized.

In the method of Japanese Patent Laid-Open No. 2000-3905, measurements are made without opening the processing chamber to the air and a state of the reaction product deposited on the reflecting mirror is monitored, but a state of a reaction product deposited on parts in the chamber cannot be recognized. Only information on the location of the reflecting mirror can be obtained.

Further, since the chamber window is used, a temporal variation occurs due to the influence of a reaction product deposited on the chamber window, and thus an accurate measurement cannot be performed.

Moreover, the parts in the processing chamber wear due to a continuous operation and such wear is hard to detect.

An object of the present invention is to provide a semiconductor manufacturing system which can recognize a state in a processing chamber more correctly than the conventional art without opening the processing chamber to the air, improve the working ratio of the semiconductor manufacturing system, and prevent a reduction in yield.

### DISCLOSURE OF THE INVENTION

A semiconductor manufacturing system according to the first aspect of the present invention is a semiconductor manufacturing system comprising a processing chamber and a movable member moving in and out of the processing chamber, the movable member having a sensor for observing a state in the processing chamber. With this configuration, the sensor makes it possible to observe a state in the processing chamber without opening the processing chamber to the air, thereby correctly recognizing timing of maintenance of the semiconductor manufacturing system.

A semiconductor manufacturing system according to the second aspect of the present invention is the semiconductor manufacturing system of the first aspect, further comprising a light source for observing the inside of the processing chamber. With this configuration, the inside of the processing chamber can be observed more easily by the sensor. Particularly when the sensor is an image pickup device, a clear image can be obtained. Particularly when the light source is mounted on the movable member, a sufficient light quantity can be obtained even in the presence of deposit on a window for passing light from the light source into the processing chamber, as compared with a light source mounted outside the processing chamber.

A semiconductor manufacturing system according to the third aspect of the present invention is the semiconductor manufacturing system of the first aspect, further comprising a data processing system for processing output data from the sensor to decide an abnormality in the processing chamber. With this configuration, it is possible to decide an abnormality in the processing chamber without the necessity for a human decision. Particularly when the sensor is an image pickup device, image data obtained by the image pickup device in the processing chamber is subjected to image processing by software stored in the system, so that an abnormality including the exfoliation of a deposited film can be detected in the processing chamber.

A semiconductor manufacturing system according to the fourth aspect of the present invention is the semiconductor manufacturing system of the first aspect, wherein the movable member is an arm for transferring a wafer into the processing chamber. With this configuration, it is not necessary to provide a movable member moving in and out of the processing chamber in addition to the arm for transferring the wafer into the processing chamber, thereby simplifying the configuration of the system.

A semiconductor manufacturing system according to the fifth aspect of the present invention is the semiconductor manufacturing system of the first aspect, wherein the movable member is different from an arm for transferring a wafer into the processing chamber. With this configuration, the position of the movable member is freely controlled in the processing chamber, so that information can be obtained in the processing chamber more widely than the sensor mounted on a wafer transfer arm.

A semiconductor manufacturing system according to the sixth aspect of the present invention is the semiconductor manufacturing system of the first aspect, wherein the sensor is imaging unit. With this configuration, an abnormality including the exfoliation of the deposited film can be detected in the processing chamber based on image data obtained by the imaging unit in the processing chamber.

A semiconductor manufacturing system according to the seventh aspect of the present invention is the semiconductor manufacturing system of the first aspect, wherein the sensor is a distance sensor for measuring a distance. With this configuration, the necessity for maintenance can be decided by measuring a distance between the movable member and a part mounted in the processing chamber.

A semiconductor manufacturing system according to the eighth aspect of the present invention is the semiconductor manufacturing system of the first aspect, wherein the distance sensor has a light-emitting device for emitting detection light to a part in the processing chamber and a light-receiving device for detecting light reflected from the part.

A semiconductor manufacturing system according to the ninth aspect of the present invention is the semiconductor manufacturing system of the first aspect, further comprising a level sensor for detecting a height of the movable member in addition to the sensor, wherein a decision result of a data processing system is controlled based on the detection of the level sensor. With this configuration, it is possible to prevent timing of maintenance from being erroneously detected due to a displacement in the height of the movable member, thereby accurately detecting timing of maintenance.

A semiconductor manufacturing system according to the tenth aspect of the present invention is the semiconductor manufacturing system of the first aspect, further comprising a storage chamber which is adjacent to the processing chamber and stores the movable member. With this configuration, it is possible to move the movable member into the processing chamber.

A method of manufacturing a semiconductor device according to the eleventh aspect of the present invention is such that when the semiconductor device is manufactured by carrying a wafer in and out of a processing chamber, during the transfer of the wafer into the processing chamber, during the transfer of the wafer out of the processing chamber, or in idle time during which no processing is performed in the processing chamber, the method comprises obtaining data by observing a state in the processing chamber with a sensor attached to a movable member moving in and out of the processing chamber, and managing the state of the processing chamber by processing the obtained data in a data processing system and deciding the presence or absence of an abnormality in the processing chamber. With this configuration, it is possible to obtain data in the processing chamber to accurately detect timing of maintenance in the manufacturing process of the semiconductor device while minimizing the influence on the manufacturing process.

A method of manufacturing a semiconductor device according to the twelfth aspect of the present invention is such that when the semiconductor device is manufactured by carrying a wafer in and out of a processing chamber, during the transfer of the wafer into the processing chamber, during the transfer of the wafer out of the processing chamber, or in idle time during which no processing is performed in the processing chamber, the method comprises obtaining image data by observing a state in the processing chamber with imaging unit attached to a movable member moving in and out of the processing chamber, and managing the state of the processing chamber by processing the obtained image data in a data processing system and deciding the presence or absence of an abnormality in the processing chamber. With this configuration, it is possible to obtain data in the processing chamber to accurately detect timing of maintenance in the manufacturing process of the semiconductor device while minimizing the influence on the manufacturing process. Particularly, by comparing image data obtained by the imaging unit and image data obtained beforehand for each thickness of a reaction product deposited on a part mounted in the processing chamber, the thickness of the deposited reaction product in the processing chamber can be calculated. Thus, it is possible to decide the necessity for maintenance of the semiconductor manufacturing system before an abnormality including the exfoliation of a deposited film actually occurs in the processing chamber. The image data obtained beforehand is stored as a database in a storage device and a comparison with the image data obtained by the imaging unit is processed by the data processing system, so that timing of maintenance can be correctly detected at high speed.

A method of manufacturing a semiconductor device according the thirteenth aspect of the present invention is the method of the eleventh aspect, wherein the movable member moving in and out of the processing chamber is an arm for transferring the wafer into the processing chamber or different from an arm for transferring the wafer into the processing chamber.

A method of manufacturing a semiconductor device according to the fourteenth aspect of the present invention the method of the twelfth aspect, wherein the movable member moving in and out of the processing chamber is an arm for transferring the wafer into the processing chamber or different from an arm for transferring the wafer into the processing chamber.

With this configuration, when using the arm for transferring the wafer into the processing chamber, timing of maintenance can be detected from a state of the reaction product deposited on the part in the transfer path of the wafer. When using the movable member different from the arm for transferring the wafer into the processing chamber, an operation is performed in the idle state of the processing chamber to obtain data in the processing chamber. Thus, as compared with data obtained in the processing chamber during the transfer of the wafer into the processing chamber or the transfer of the wafer out of the processing chamber, it is possible to more specifically inspect a state in the processing chamber and obtain information in the processing chamber more widely, thereby more correctly detecting timing of maintenance at higher speed.

A method of manufacturing a semiconductor device according to the fifteenth aspect of the present invention, is such that when the semiconductor device is manufactured by carrying a wafer in and out of a processing chamber, during the transfer of the wafer into the processing chamber, during the transfer of the wafer out of the processing chamber, or in idle time during which no processing is performed in the processing chamber, the method comprises measuring an amount of wear of the part in the processing chamber by measuring a distance from the part with a distance sensor attached to a movable member moving in and out of the processing chamber, and managing a state of the processing chamber by detecting the life of the part and deciding the presence or absence of an abnormality in the processing chamber. With this configuration, it is possible to detect the wear of the part mounted in the processing chamber, thereby deciding the necessity for maintenance of the semiconductor manufacturing system without opening the processing chamber to the air.

A method of manufacturing a semiconductor device according to the sixteenth aspect of the present invention is the method of the fifteenth aspect, wherein the life of the part is calculated according to the distance from the part mounted in the processing chamber, the distance being measured using the distance sensor. Thus, it is possible to decide the necessity for maintenance of the semiconductor manufacturing system without opening the processing chamber to the air.

As described above, according to the semiconductor manufacturing system and the method of manufacturing the semiconductor device of the present invention, it is possible to accurately recognize timing of maintenance of the system without opening the processing chamber to the air.

### BRIEF DESCRIPTION OF THE DRAWINGS

FIGS. 1A and 1B are a plan view and a sectional view of a semiconductor manufacturing system and FIG. 1C is a plan view of a wafer transfer arm according to (Embodiment 1) of the present invention;

FIGS. 2A and 2B are a sectional view of a carry-in process and a plan view of the wafer transfer arm according to (Embodiment 1);

FIGS. 3A to 3D are sectional views of the carry-in/out process of (Embodiment 1);

FIG. 4A is a sectional view of a semiconductor manufacturing system and FIG. 4B is a plan view of a wafer transfer arm according to (Embodiment 2) of the present invention;

FIG. 5A is a sectional view of a semiconductor manufacturing system and FIG. 5B is a plan view of a wafer transfer arm according to (Embodiment 3) of the present invention;

FIG. 6 is a sectional view of a semiconductor manufacturing system according to (Embodiment 4) of the present invention;

FIG. 7 is a sectional view of a semiconductor manufacturing system according to (Embodiment 5) of the present invention;

FIG. 8 is a sectional view of a semiconductor manufacturing system according to (Embodiment 6) of the present invention;

FIG. 9 is a sectional view of a semiconductor manufacturing system according to (Embodiment 7) of the present invention; and

FIGS. 10A and 10B are a plan view and a sectional view of a semiconductor manufacturing system according to (Embodiment 8) of the present invention.

### DESCRIPTION OF THE EMBODIMENTS

The following will describe embodiments of the present invention in accordance with the accompanying drawings.

### Embodiment 1

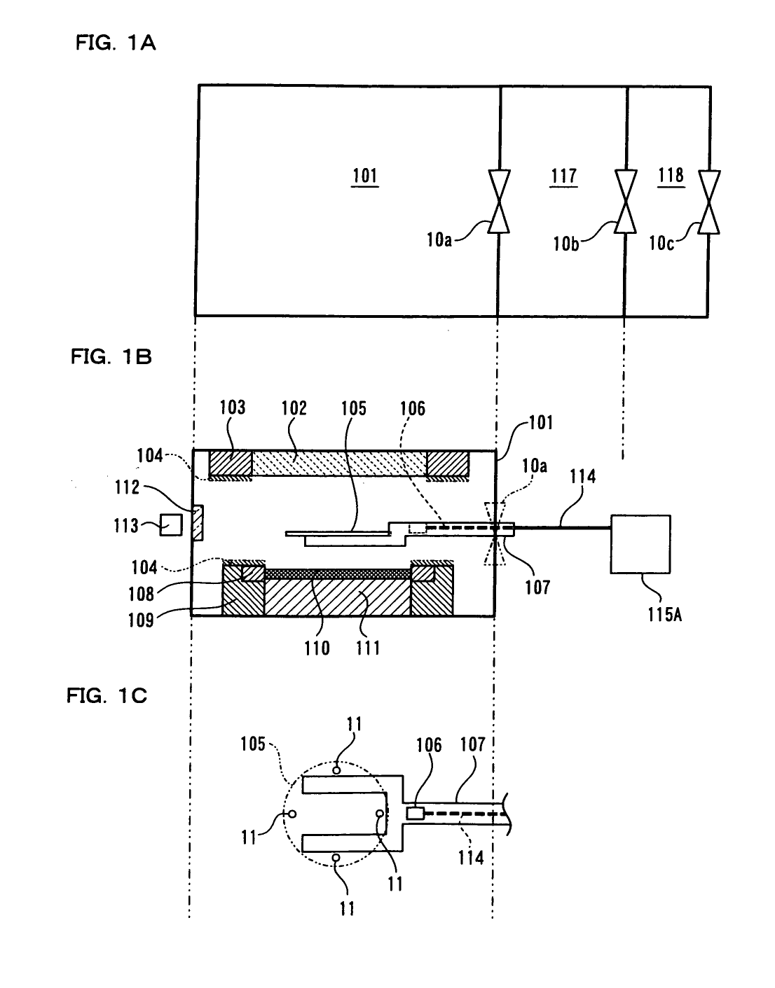

FIGS. 1 to 3 show a semiconductor manufacturing system according to (Embodiment 1) of the present invention.

In this embodiment, the semiconductor manufacturing system is a parallel-plate dry etching system.

As shown in FIGS. 1A, 1B, and 1C, in an etching chamber 101 serving as a processing chamber for performing dry etching, a cassette chamber 118 is provided via a transfer chamber 117. The transfer chamber 117 comprises a wafer transfer arm 107 serving as a movable member for carrying in/out a wafer 105, which is a workpiece, between the cassette chamber 118 and the etching chamber 101. A partition wall between the etching chamber 101 and the transfer chamber 117 has a gate 10a with an air tight structure. A partition wall between the transfer chamber 117 and the cassette chamber 118 has a gate 10b with an air tight structure. The cassette chamber 118 has a gate 10c for taking in/out a cassette (not shown) storing the wafer 105.

For example, in the etching chamber 101 for etching the wafer 105, a silicon oxide film or the like formed on the wafer 105 is etched under the following conditions:

Power of 60 MHz and 2000 W is supplied to an upper electrode 102, and power of 2 MHz and 1500 W is supplied to a lower electrode 111. Mixed gas of C5F8/Ar/O2(=20 sccm/500 sccm/20 sccm) is supplied as etching gas into the etching chamber 101. A pressure in the etching chamber 101 is set at 4 Pa. Etching time is set at 2 minutes.

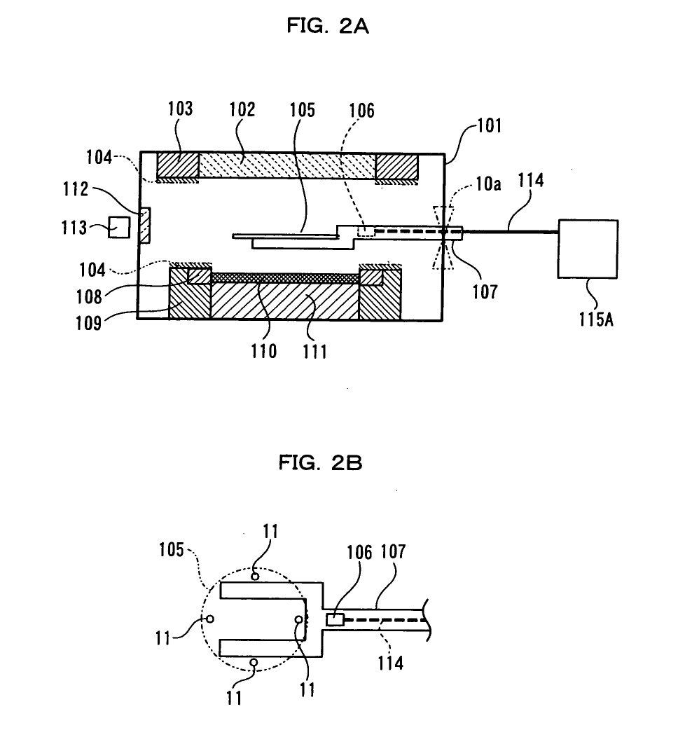

During etching, the gate 10a of the etching chamber 101 is opened after the internal pressures of the etching chamber 101 and the transfer chamber 117 are adjusted, and the wafer 105 is placed on the wafer transfer arm 107 from the opening of the gate 10a and moved above an electrostatic chuck 110. Then, as shown in FIGS. 2A and 2B, pins 11 rise from the lower electrode 111 and lift the wafer 105 from the top surface of the wafer transfer arm 107.

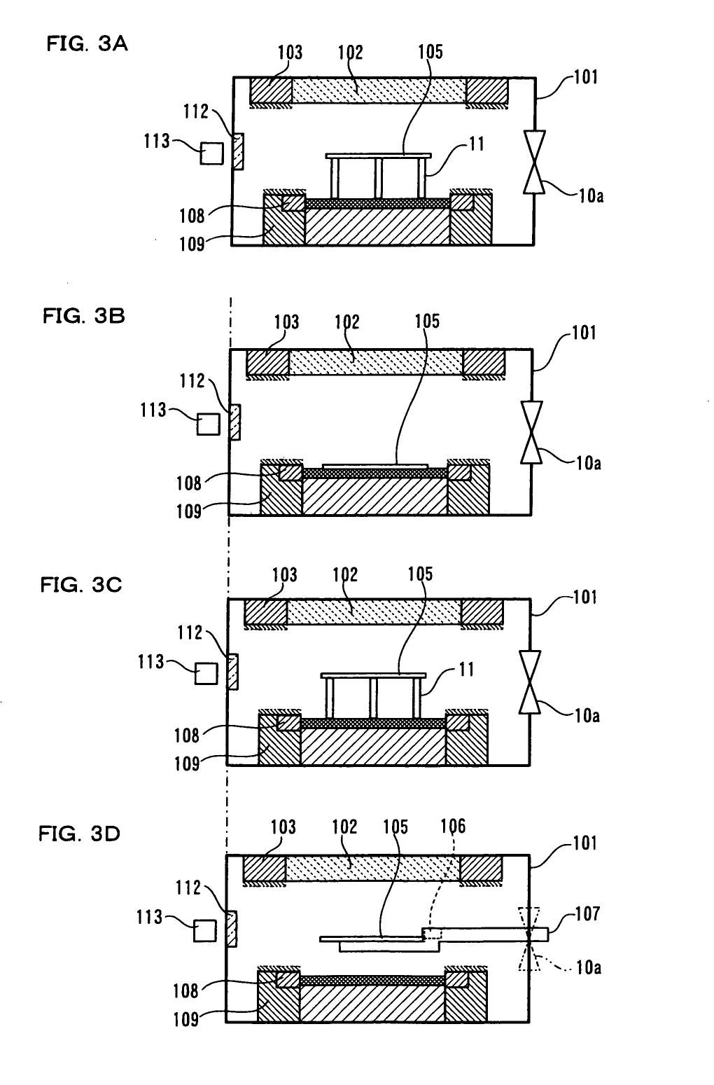

In this state, the wafer transfer arm 107 moves back to the transfer chamber 117, the gate 10a is closed as shown in FIG. 3A, and the pins 11 move down to place the wafer 105 on the electrostatic chuck 110 as shown in FIG. 3B. Reference numeral 108 denotes a focus ring.

In this embodiment, as shown in FIGS. 1B and 1C, on a position adjacent to the wafer 105 on a side (top surface) of the wafer transfer arm 107 where the wafer 105 is placed, a camera 106 using a CCD (Charge Coupled Device) serving as imaging unit is mounted as a sensor.

At the completion of etching of the wafer 105, as shown in FIG. 3C, the pins 11 rise to lift the wafer 105, the gate 10a is opened after the internal pressures of the etching chamber 101 and the transfer chamber 117 are adjusted, and the wafer transfer arm 107 comes below the wafer 105. In this state, as shown in FIG. 3C, the pins 11 move down to place the wafer 105 on the wafer transfer arm 107. The wafer transfer arm 107 having received the wafer 105 carries the wafer 105 out of the etching chamber 101, the gate 10a is closed, the gate 10b is opened after the internal pressures of the transfer chamber 117 and the cassette chamber 118 are adjusted, and the processed wafer 105 is transferred to the cassette positioned in the cassette chamber 118.

After the processing routine is repeated, as shown in FIG. 1B, a CF deposited film 104 of an etching reaction product is deposited on a surface of an upper insulating ring 103, a surface of a lower insulating ring 109, and so on in the etching chamber 101.

When the thickness of the deposited film 104 is too large or when the thickness of the deposited film 104 is changed by an abnormality of some kind, the deposited film 104 is peeled off and causes particles and low yields.

Hence, in (Embodiment 1), an operation system is configured as follows: the inside of the etching chamber 101 is illuminated by a light source 113 through a chamber window 112, for example, every time the wafer 105 is transferred to the etching chamber 101 by the wafer transfer arm 107, and the image data of the upper insulating ring 103 is obtained by the camera 106.

In this operation system, the image data obtained by the camera 106 is transmitted to a data processing system 115A through a cable 114 and is subjected to image processing by the data processing system 115A, so that it is decided whether the deposited film 104 on the surface of the upper insulating ring 103 is peeled off or not and the necessity for maintenance of the system is decided.

In this way, the exfoliation of the deposited film 104 in the etching chamber 101 can be confirmed for each processed wafer, thereby accurately recognizing timing of maintenance. Thus, it is possible to prevent unnecessary maintenance, prevent the working ratio of the system from decreasing, and prevent low yields caused by processing in an abnormal system where the deposited film 104 is peeled off.

When the wafer 105 is carried in the etching chamber 101 and when the wafer 105 is carried out of the etching chamber 101, the inside of the transfer chamber 117 is evacuated beforehand after the gate 10a between the etching chamber 101 and the transfer chamber 117 is closed, so that the inside of the etching chamber 101 is not exposed to the air. With this configuration, the deposited film 104 in the etching chamber 101 becomes more resistant to exfoliation.

When the camera 106 is mounted on the undersurface of the wafer transfer arm 107, it is possible to observe the deposited film 104 on the surface of the lower insulating ring 109. When the camera 106 is mounted on a side of the wafer transfer arm 107, it is possible to observe the deposited film 104 on the inner wall of the etching chamber 101.

The number of the cameras 106 and the position of the camera 106 are not limited to those of the present embodiment. In other words, two or more cameras 106 may be provided and the camera 106 may be mounted on the undersurface, a side, or the end of the wafer transfer arm 107.

### Embodiment 2

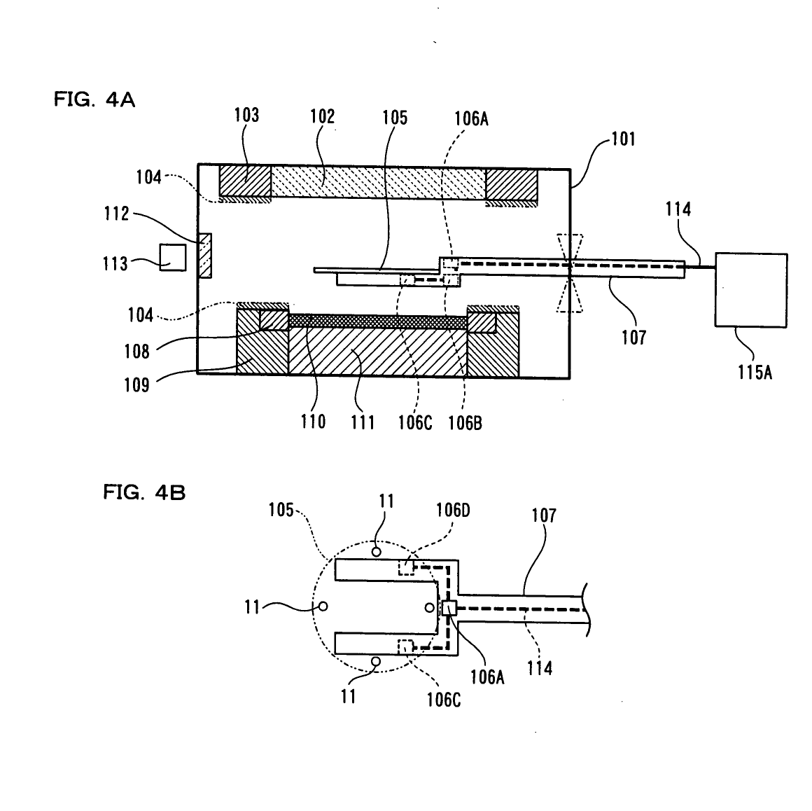

FIGS. 4A and 4B show a semiconductor manufacturing system according to (Embodiment 2) of the present invention.

(Embodiment 2) is different from (Embodiment 1) of FIG. 1 in the number of cameras 106 and the locations of the cameras 106. Other configurations are identical to those of (Embodiment 1).

In FIGS. 4A and 4B, a first camera 106A, a second camera 106B, and third cameras 106C and 106D are mounted on a wafer transfer arm 107. The first to third cameras 106A to 106D are connected to a data processing system 115A via a cable 114.

The first camera 106A is mounted on a side (top surface) of the wafer transfer arm 107 where a wafer 105 is placed and the first camera 106A is adjacent to the wafer 105. The second camera 106B is mounted on the opposite side (undersurface) from the side where the wafer 105 is placed. The third cameras 1 06C and 106D are mounted on the other sides of the wafer transfer arm 107.

An operation system is configured as follows:

In the present embodiment, the operation system is configured such that the inside of an etching chamber 101 is illuminated by a light source 113 through a chamber window 112, for example, every time the wafer 105 is transferred into the etching chamber 101 by the wafer transfer arm 107, and image data in the etching chamber 101 is obtained by the first to third cameras 106A to 106C.

In this case, the image data of an upper insulating ring 103, a lower insulating ring 109, and the inner wall of the etching chamber 101 is obtained by the first to third cameras 106A to 106D, respectively.

The image data from the first to third cameras 106A to 106D is transmitted to the data processing system 115A through the cable 114 and is subjected to image processing by the data processing system 115A, it is decided whether a deposited film 104 on the upper insulating ring 103, the lower insulating ring 109, and the inner wall of the etching chamber 101 is peeled off or not, and the necessity for maintenance of the system is decided.

In this way, according to (Embodiment 2), the exfoliation of the deposited film 104 in the chamber can be confirmed for each processed wafer, thereby accurately recognizing timing of maintenance. Comparing with (Embodiment 1), the exfoliation of the deposited film 104 can be confirmed on two or more points in the etching chamber 101 for each processed wafer, thereby recognizing timing of maintenance more accurately than (Embodiment 1).

Thus, it is possible to prevent unnecessary maintenance, prevent the working ratio of the system from decreasing, and prevent low yields caused by processing in an abnormal system where the deposited film 104 is peeled off.

The number of the first to third cameras 106A to 106D and the positions of the cameras 106A to 106D are not limited to those of the present embodiment. In other words, a plurality of first and second cameras 106A and 106B may be provided. The number of the third cameras 106C and 106D may be one or three or more. The third cameras 106C and 106D may be mounted on the end of the wafer transfer arm 107.

### Embodiment 3

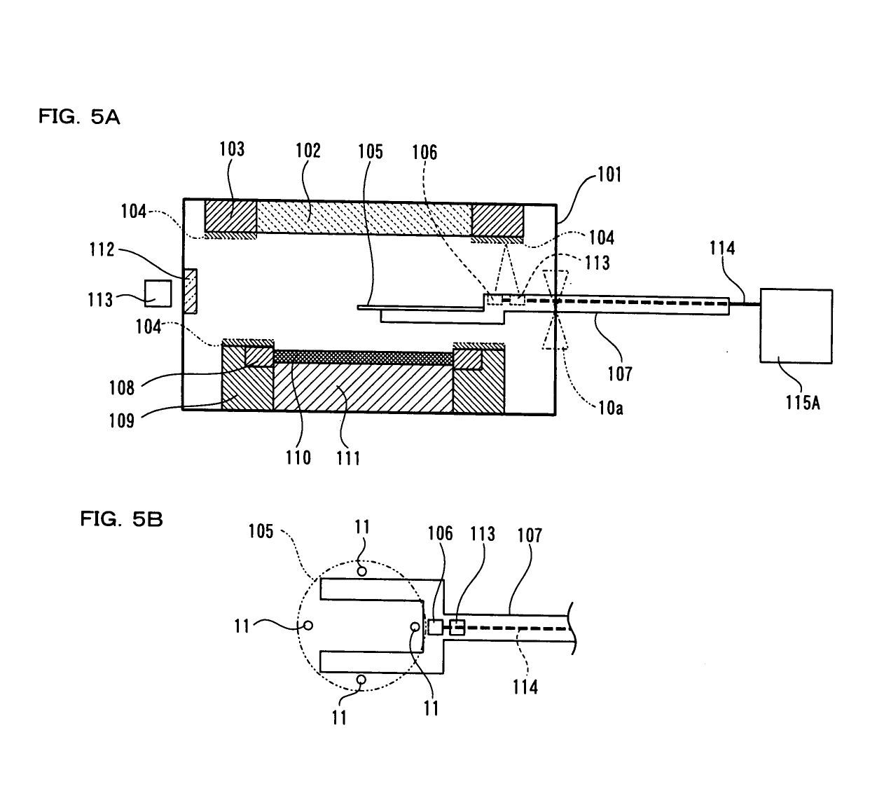

FIGS. 5A and 5B show a semiconductor manufacturing system according to (Embodiment 3) of the present invention. (Embodiment 3) is different from (Embodiment 1) of FIG. 1 in that a light source 113 for illuminating the inside of an etching chamber 101 is mounted on a side (top surface) of a wafer transfer arm 107 where a wafer 105 is placed and the light source 113 is adjacent to a camera 106 in FIGS. 5A and 5B. Other configurations are identical to those of (Embodiment 1).

An operation system is configured as follows:

In the present embodiment, the operation system is configured such that the inside of the etching chamber 101 is illuminated by the light source 113 mounted on the wafer transfer arm 107, for example, every time the wafer 105 is transferred to the etching chamber 101 by the wafer transfer arm 107, and image data in the etching chamber 101 is obtained by the camera 106.

In this operation system, the image data obtained by the camera 106 is transmitted to a data processing system 115A through a cable 114 and is subjected to image processing by the data processing system 115A, so that it is decided whether a deposited film 104 on a surface of an upper insulating ring 103 is peeled off or not and the necessity for maintenance of the system is decided.

In this way, the upper insulating ring 103 is illuminated by the light source 113 from a close position, and thus the exfoliation of the deposited film 104 in the etching chamber 101 can be confirmed more clearly than (Embodiment 1), thereby accurately recognizing timing of maintenance.

In this way, according to (Embodiment 3), the exfoliation of the deposited film 104 in the etching chamber 101 can be confirmed for each processed wafer, thereby accurately recognizing timing of maintenance. Comparing with (Embodiment 1), a certain light quantity can be obtained even when a quantity of light from the outside of the chamber is small due to the influence of an etching product deposited on a chamber window 112.

With this configuration, it is possible to prevent unnecessary maintenance, prevent the working ratio of the system from decreasing, and prevent low yields caused by processing in an abnormal system where the deposited film 104 is peeled off.

The number of the light sources 113 and the position of the light source 113 are not limited to those of the present embodiment. In other words, two or more light sources 113 may be provided and the light source 113 may be mounted on the undersurface, a side, or the end of the wafer transfer arm 107. In these cases, the light source 113 preferably adjoins to the camera 106.

When the camera 106 is mounted on the opposite side (undersurface) from the side of the wafer transfer arm 107 where the wafer 105 is placed, the light source 113 is mounted on the undersurface of the wafer transfer arm 107, so that the deposited film 104 on a surface of a lower insulating ring 109 can be clearly observed.

When the camera 106 is mounted on a side of the wafer transfer arm 107, the deposited film 104 on the inner wall of the etching chamber 101 can be observed by mounting the light source 113 on the side of the wafer transfer arm 107.

Also in (Embodiment 2), the same effect can be expected by mounting the light source 113 near the first to third cameras 106A to 106D.

### Embodiment 4

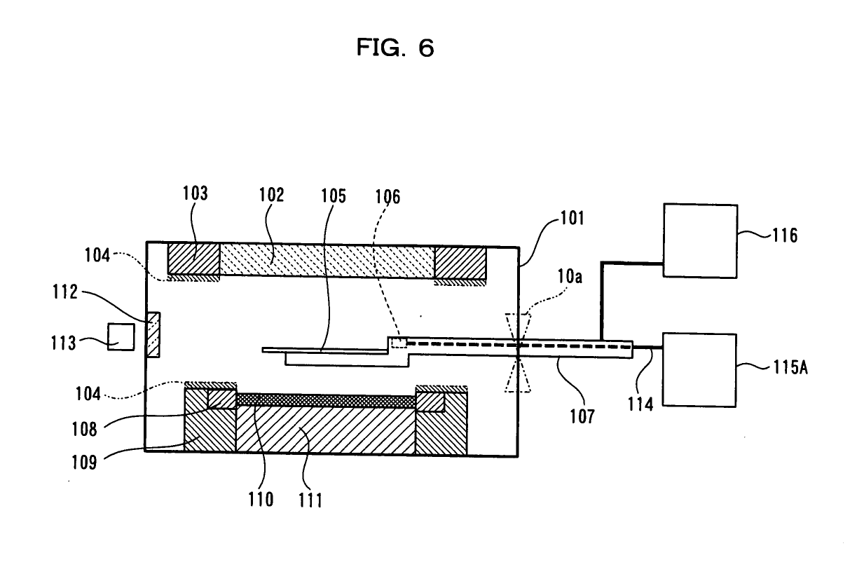

FIG. 6 shows a semiconductor manufacturing system according to (Embodiment 4) of the present invention.

(Embodiment 4) is different from (Embodiment 1) of FIG. 1 as follows: in the operation system of (Embodiment 1), image data is obtained by the camera 106 every time the wafer 105 is transferred to the etching chamber 101 through the transfer path of the wafer 105 by the wafer transfer arm 107, whereas in FIG. 6, a wafer transfer arm controller 116 for controlling the position of a wafer transfer arm 107 has the configuration below. Other configurations are identical to those of (Embodiment 1).

The wafer transfer arm controller 116 is configured such that the wafer transfer arm 107 is moved to a given point to be observed in a chamber 101 and detailed data in the etching chamber 101 is obtained in a time during which processing is not performed in the etching chamber 101 (idle time).

With this configuration, regarding data obtained by the camera 106 while processing is not performed in the etching chamber 101 (idle time), for example, during the idle time of the etching chamber 101 after the completion of lot processing, the wafer transfer arm 107 is moved and data is obtained beforehand according to a transfer recipe where observation points are set.

For example, image data on two or more points in the plane of an upper insulating ring 103 is obtained by the camera 106 mounted on the top surface of the wafer transfer arm 107. The image data is transmitted to a data processing system 115A through a cable 114 and is subjected to image processing by the data processing system 115A, so that it is decided whether a deposited film 104 is peeled off or not and the necessity for maintenance of the system is decided.

In this way, according to (Embodiment 4), the wafer transfer arm 107 is moved to a given point to be observed in a chamber 101 during the idle time of the etching chamber 101, so that detailed data in the etching chamber 101 can be obtained. Thus, detailed information not observable in fixed point observation for each processed wafer in (Embodiment 1) can be obtained in the etching chamber 101 and timing of maintenance can be recognized more accurately. Thus, it is possible to prevent unnecessary maintenance, prevent the working ratio of the system from decreasing, and prevent low yields caused by processing in an abnormal system where the deposited film 104 is peeled off.

This configuration can be similarly implemented when cameras 106A to 106D are mounted on the wafer transfer arm 107 as (Embodiment 2) and (Embodiment 3).

### Embodiment 5

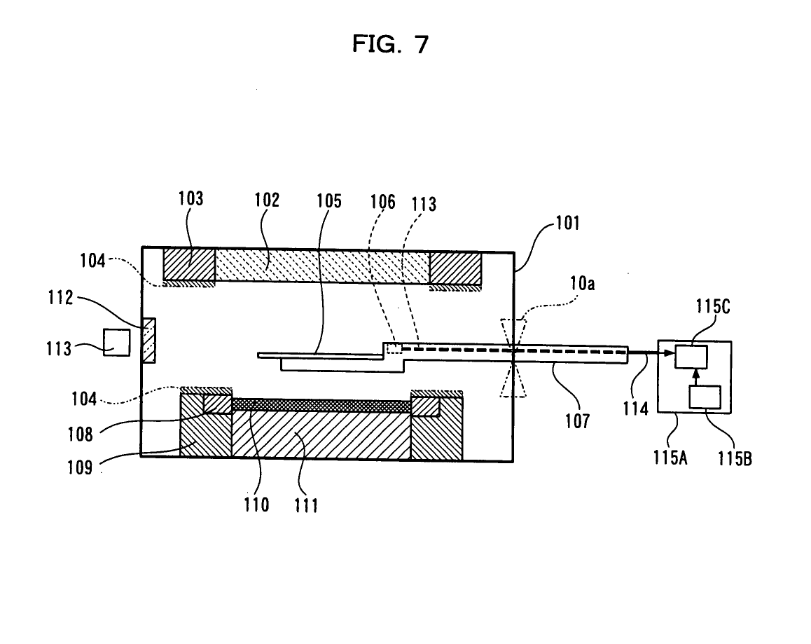

FIG. 7 shows a semiconductor manufacturing system according to (Embodiment 5) of the present invention.

(Embodiment 5) is different from (Embodiment 1) of FIG. 1 as follows: in the data processing system 115A of (Embodiment 1), image data obtained by the camera 106 is processed to decide whether the deposited film 104 is peeled off or not, whereas in (Embodiment 5) of FIG. 7, the thickness of a deposited film 104 is calculated according to image data obtained by a camera 106 and the necessity for maintenance of the system is decided according to the calculated thickness of the deposited film 104. Other configurations are identical to those of (Embodiment 1).

To be specific, in the present embodiment, image data on various thicknesses of the deposited film 104 on an upper insulating ring 103 is stored as a database in a storage device 115B in a data processing system 115A. Then, current image data obtained by the camera 106 and image data accumulated in the storage device 115B are compared with each other and referred to each other by an arithmetic unit 115C, so that the current thickness of the deposited film 104 is calculated.

In this way, the thickness of the deposited film 104 in a chamber is confirmed for each processed wafer and it is decided whether the deposited film 104 has a certain thickness or not. Thus, maintenance can be performed at the certain thickness before exfoliation starts. With this configuration, the occurrence of low yields caused by the exfoliation of the deposited film 104 can be reduced as compared with (Embodiment 1).

This configuration can be similarly implemented when the cameras a remounted on the wafer transfer arm 107 as (Embodiments 2 to 4).

### Embodiment 6

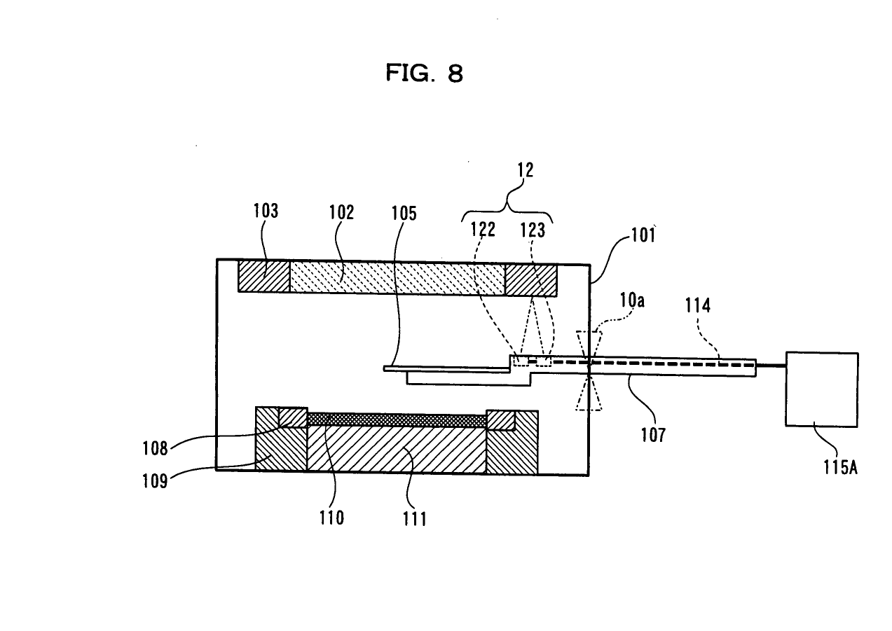

FIG. 8 shows a semiconductor manufacturing system according to (Embodiment 6) of the present invention.

(Embodiment 6) is different from (Embodiment 1) of FIG. 1 in that a distance sensor 12 is mounted as a sensor instead of the camera 106. The distance sensor 12 comprises a semiconductor laser 122 which is a light-emitting device and a photodiode 123 which is a light-receiving device.

To be specific, the semiconductor laser 122 is mounted on a side (top surface) of a wafer transfer arm 107 where a wafer 105 is placed and the semiconductor laser 122 is adjacent to the wafer 105. Further, the photodiode 123 is mounted on the top surface of the wafer transfer arm 107 and is adjacent to the semiconductor laser 122.

When etching is performed as described in (Embodiment 1), wear occurs on parts in an etching chamber 101, e.g., an upper insulating ring 103 and a lower insulating ring 109. When the thickness of the parts is too small as compared with an initial state, characteristics change and particles occur, thereby reducing yields.

Hence, an operation system of the present embodiment is configured as follows:

Every time each wafer 105 is transferred to the etching chamber 101 by the wafer transfer arm 107, laser light is emitted to the upper insulating ring 103 by the semiconductor laser 122 mounted on the top surface of the wafer transfer arm 107. The laser light having been incident on the upper insulating ring 103 and returned therefrom is received by the photodiode 123.

A detection signal of the photodiode 123 is transmitted to a data processing system 115A through a cable 114, a time during which laser light is incident on the upper insulating ring 103 and returned therefrom is measured in the data processing system 115A, and a distance between the upper insulating ring 103 and the wafer transfer arm 107 is measured accordingly. The amount of wear of the upper insulating ring 103 is measured according to a difference between the determined distance between the upper insulating ring 103 and the wafer transfer arm 107 and a distance between the wafer transfer arm 107 and the upper insulating ring 103 in new condition, and the necessity for maintenance of the system is decided.

In this way, the wear of the upper insulating ring 103 in the etching chamber 101 can be confirmed for each processed wafer, thereby accurately recognizing timing of maintenance. Thus, it is possible to prevent unnecessary maintenance, prevent the working ratio of the system from decreasing, and prevent low yields caused by changes in characteristics and the occurrence of particles due to wear of the parts in the chamber.

When the semiconductor laser 122 and the photodiode 123 are placed on the opposite side (undersurface) from the side where the wafer 105 of the wafer transfer arm 107 is placed, the wearing state of the lower insulating ring 109 is measured and the amount of wear of the lower insulating ring 109 is measured according to a difference between a distance between the lower insulating ring 109 and the wafer transfer arm 107 and a distance between the wafer transfer arm 107 and the lower insulating ring 109 in new condition, so that the necessity for maintenance of the system can be decided. The distance sensors 12 may be provided on both surfaces of the wafer transfer arm 107 to confirm the amount of wear of the upper insulating ring 103 and the lower insulating ring 109 for each processed wafer.

### Embodiment 7

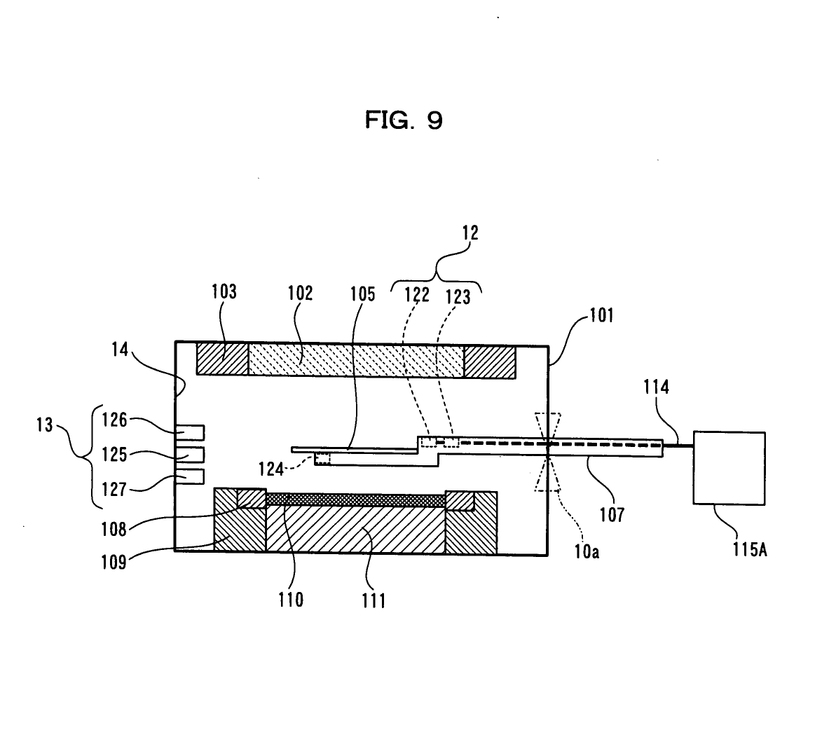

FIG. 9 shows a semiconductor manufacturing system according to (Embodiment 7) of the present invention.

In (Embodiment 6) of FIG. 8, when the wafer transfer arm 107 is displaced in height, the accuracy of measuring the amount of wear of the upper insulating ring 103 is reduced and the necessity for maintenance of the system cannot be properly decided. (Embodiment 7) shown in FIG. 9 is different in that a level sensor 13 is provided as a sensor for measuring a displacement in the height of a wafer transfer arm 107. Other configurations are identical to those of (Embodiment 6).

The level sensor 13 comprises a semiconductor laser 124 which is a light-emitting device and photodiodes 125, 126, and 127 which are light-receiving devices.

The semiconductor laser 124 is attached to the end of the wafer transfer arm 107 so as to emit laser light to an inner wall 14 of an etching chamber 101. The photodiodes 125, 126, and 127 are attached to the inner wall 14 of the etching chamber 101. The photodiode 125 is attached almost as high as the initial position of the semiconductor laser 124 immediately after maintenance. The photodiode 126 is attached higher than the photodiode 125. The photodiode 127 is attached lower than the photodiode 125.

An operation system of the present embodiment is configured as follows:

Every time a wafer 105 is carried to the etching chamber 101 by the wafer transfer arm 107, laser light is emitted to an upper insulating ring 103 by the semiconductor laser 122, and laser light having been reflected and returned from the upper insulating ring 103 is received by the photodiode 123. A data processing system 115A measures a time during which the laser light is incident on the upper insulating ring 103 and returned therefrom, and a distance between the upper insulating ring 103 and the wafer transfer arm 107 is measured accordingly. The amount of wear of the upper insulating ring 103 is measured according to a difference between the determined distance between the upper insulating ring 103 and the wafer transfer arm 107 and a distance between the wafer transfer arm 107 and the upper insulating ring 103 in new condition, and the necessity for maintenance of the system is decided. When the data processing system 115A detects that the photodiode 125 has received laser light from the semiconductor laser 124, a decision result on the necessity for maintenance of the system is processed as a valid result. When the data processing system 115A detects that the photodiode 126 or the photodiode 127 has received laser light from the semiconductor laser 124, a decision on the necessity for maintenance of the system based on a difference from the distance between the wafer transfer arm 107 and the upper insulating ring 103 in new condition is processed as an invalid decision. An instruction to return the height of the wafer transfer arm 107 to the initial position is given to the outside.

With this configuration, in the case of a displacement in the height of the wafer transfer arm 107 from the initial position, a decision on the necessity for maintenance of the system is made invalid. Thus, it is possible to prevent unnecessary maintenance and prevent the working ratio of the system from decreasing.

In the case where a level difference between the attached photodiodes 125 and 126 and a level difference between the attached photodiodes 125 and 127 are already known, when it is decided that the photodiode 126 has received laser light from the semiconductor laser 124, a difference from the distance between the wafer transfer arm 107 and the upper insulating ring 103 in new condition is corrected according to the level difference between the photodiodes 125 and 126. The amount of wear of the upper insulating ring 103 is measured according to a difference between the corrected difference and the distance between the wafer transfer arm 107 and the upper insulating ring 103 in new condition, and the necessity for maintenance of the system is decided. With this configuration of the data processing system 115A, it is possible to more properly decide the necessity for maintenance of the system.

Similarly, in the configuration of the data processing system 115A, when it is decided that the photodiode 127 has received laser light from the semiconductor laser 124, a difference from the distance between the wafer transfer arm 107 and the upper insulating ring 103 in new condition is corrected according to the level difference between the photodiodes 125 and 127. The amount of wear of the upper insulating ring 103 is measured according to a difference between the corrected difference and the distance between the wafer transfer arm 107 and the upper insulating ring 103 in new condition, and the necessity for maintenance of the system is decided.

In (Embodiment 7), the wear of the upper insulating ring 103 is detected. The present embodiment can be similarly implemented also when detecting the wear of the lower insulating ring 109.

In this way, a displacement in the height of the wafer transfer arm 107 from the initial position is measured and thus a distance measurement can be correctly performed with a corrected displacement in the height of the wafer transfer arm 107. With this configuration, it is possible to more accurately measure the amount of wear of parts in the chamber and decide the necessity for maintenance of the system.

Therefore, according to (Embodiment 7), it is possible to measure the amount of wear of parts in the etching chamber 101 more accurately than (Embodiment 6), thereby correctly recognizing timing of maintenance. Thus, it is possible to prevent unnecessary maintenance, prevent the working ratio of the system from decreasing, and prevent low yields caused by changes in characteristics and the occurrence of particles due to the wear of the parts in the chamber.

The number of light-receiving devices for measuring a displacement in the height of the wafer transfer arm 107 in the level sensor 13 is not limited to three, and thus the number of light-receiving devices may be two or four or more. (Embodiment 8)

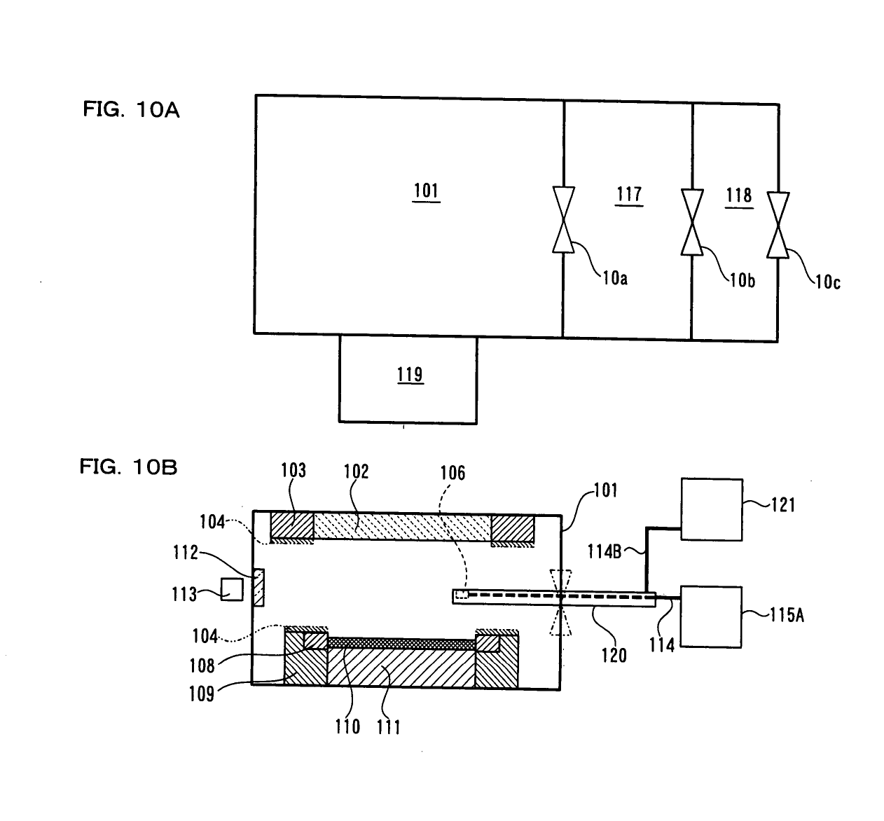

FIG. 10 shows a semiconductor manufacturing system according to (Embodiment 8) of the present invention.

In (Embodiment 1) of FIG. 1, the sensor for observing the inside of the etching chamber 101 is provided on the wafer transfer arm 107, whereas in (Embodiment 8), a camera 106 acting as a sensor is mounted on a robot arm 120 which is different from a wafer transfer arm 107.

Differences will be specifically discussed below.

The robot arm 120 stored in a robot arm storage chamber 119 adjacent to an etching chamber 101 is a revolute industrial robot which can not only move forward and backward like the wafer transfer arm 107 but also move its end to observe a specified part in the etching chamber 101. The camera 106 is mounted on the top surface of the robot arm 120 (on the side of an upper electrode 102).

The robot arm 120 is controlled by a robot arm controller 121 through a cable 114B so as to move in X, Y, and Z directions.

In the present embodiment, the robot arm 120 for data acquisition is moved to a given point to be observed in the chamber 101 and detailed data in the chamber 101 is obtained in a time during which processing is not performed in the etching chamber 101 (idle time). For example, in the event of an irregular problem, image data in the etching chamber 101 is obtained, the cause of an abnormality is investigated, and the necessity for maintenance of the system is decided.

As described above, when the robot arm 120 has a sensor, it is possible to obtain information in the etching chamber 101. The inside of the etching chamber 101 is hard to observe with a sensor on the wafer transfer arm 107 because the sensor may come into contact with a chamber wall. With this configuration, image data in the etching chamber 101 can be obtained in the event of an irregular problem and the cause of an abnormality can be investigated without exposure to the air. Thus, it is possible to prevent unnecessary maintenance, prevent the working ratio of the system from decreasing, and prevent low yields caused by processing in an abnormal system.

In (Embodiment 8), the robot arm 120 is mounted in the robot arm storage chamber 119. A similar configuration can be obtained by mounting the robot arm 120 in a transfer chamber 117.

In the above explanation, the robot arm 120 is an articulated arm. For example, an endoscopic device or the like using an optical fiber of an endoscope for observing the inside of an organ in medical care may act as the robot arm 120 as long as the end of the device can move to observe a specified part in the etching chamber 101.

The camera 106, the cameras 106A to 106C, the distance sensors 122 to 126, or the light source 113 on the wafer transfer arm 107 in Embodiments 2 to 7 may be mounted on the robot arm 120.

In the foregoing embodiments, imaging unit for observing the inside of the etching chamber 101 is the cameras 106, 106A, 106B, and 106C using CCDs. Image pickup devices including a CMOS sensor may be used.

In the foregoing embodiments, the distance sensor 12 is a combination of the semiconductor laser and the light-receiving elements. A light-emitting diode or the like may be used for a light source instead of the semiconductor laser.

The semiconductor manufacturing system and the method of manufacturing a semiconductor device according to the present invention are quite significant for the finer design rules of semiconductor devices, higher yields, and a higher working ratio of a facility.

What is claimed is:

1. A semiconductor manufacturing system comprising:
a processing chamber, and
a movable member moving in and out of the processing chamber,
the movable member having a sensor for observing a state in the processing chamber.

2. The semiconductor manufacturing system according to claim 1, further comprising a light source for observing inside of the processing chamber.

3. The semiconductor manufacturing system according to claim 1, further comprising a data processing system for processing output data from the sensor to decide an abnormality in the processing chamber.

4. The semiconductor manufacturing system according to claim 1, wherein the movable member is an arm for transferring a wafer into the processing chamber.

5. The semiconductor manufacturing system according to claim 1, wherein the movable member is different from an arm for transferring a wafer into the processing chamber.

6. The semiconductor manufacturing system according to claim 1, wherein the sensor is imaging unit.

7. The semiconductor manufacturing system according to claim 1, wherein the sensor is a distance sensor for measuring a distance.

8. The semiconductor manufacturing system according to claim 7, wherein the distance sensor has a light-emitting device for emitting detection light to a part in the processing chamber and a light-receiving device for detecting light reflected from the part.

9. The semiconductor manufacturing system according to claim 7, further comprising a level sensor for detecting a height of the movable member in addition to the sensor, wherein a decision result of a data processing system is controlled based on detection of the level sensor.

10. The semiconductor manufacturing system according to claim 5, further comprising a storage chamber which is adjacent to the processing chamber and stores the movable member.

11. A method of manufacturing a semiconductor device, wherein when a semiconductor device is manufactured by carrying a wafer in and out of a processing chamber, during transfer of the wafer into the processing chamber, during transfer of the wafer out of the processing chamber, or in idle time during which no processing is performed in the processing chamber, the method comprises:
obtaining data by observing a state in the processing chamber with a sensor attached to a movable member moving in and out of the processing chamber, and
managing the state of the processing chamber by processing the obtained data in a data processing system and deciding presence or absence of an abnormality in the processing chamber.

12. A method of manufacturing a semiconductor device, wherein when a semiconductor device is manufactured by carrying a wafer in and out of a processing chamber, during transfer of the wafer into the processing chamber, during transfer of the wafer out of the processing chamber, or in idle time during which no processing is performed in the processing chamber, the method comprises:
obtaining image data by observing a state in the processing chamber with imaging unit attached to a movable member moving in and out of the processing chamber, and
managing the state of the processing chamber by processing the obtained image data in a data processing system and deciding presence or absence of an abnormality in the processing chamber.

13. The method of manufacturing the semiconductor device according to claim 11, wherein the movable member moving in and out of the processing chamber is an arm for transferring the wafer into the processing chamber or different from an arm for transferring the wafer into the processing chamber.

14. The method of manufacturing the semiconductor device according to claim 12, wherein the movable member moving in and out of the processing chamber is an arm for transferring the wafer into the processing chamber or different from an arm for transferring the wafer into the processing chamber.

15. A method of manufacturing a semiconductor device, wherein when a semiconductor device is manufactured by carrying a wafer in and out of a processing chamber, during transfer of the wafer into the processing chamber, during transfer of the wafer out of the processing chamber, or in idle time during which no processing is performed in the processing chamber, the method comprises:
measuring an amount of wear of a part in the processing chamber by measuring a distance from the part with a distance sensor attached to a movable member moving in and out of the processing chamber, and
managing a state of the processing chamber by detecting life of the part and deciding presence or absence of an abnormality in the processing chamber.

16. The method of manufacturing the semiconductor device according to claim 15, wherein the life of the part is calculated according to the distance from the part mounted in the processing chamber, the distance being measured using the distance sensor.
